(19) United States
(12) Patent Application Publication
(10) Pub. No.: US 2025/0338438 A1
(43) Pub. Date: Oct. 30, 2025

(54) COMPLIANT BOARD COMPONENT-LEVEL COLD PLATE

(71) Applicant: Dell Products L.P., Round Rock, TX (US)

(72) Inventors: CHARLES WILLIAM ZIEGLER, IV, East Providence, RI (US); ERIC MICHAEL TUNKS, Austin, TX (US)

(21) Appl. No.: 18/650,286

(22) Filed: Apr. 30, 2024

(51) Int. Cl. H05K 7/20; G06F 1/20; H05K 1/02

(52) U.S. Cl. CPC H05K 7/20272; G06F 1/206; H05K 1/0203; H05K 2201/066

(57) ABSTRACT

Methods, systems, and devices for providing thermal management of data processing systems that provide computer implemented services are disclosed. To provide such services, a data processing system may include a chassis, a circuit board positioned with the chassis, and a processor positioned with the circuit board and paired with a heatsink adapted to dissipate heat generated by the processor. Additionally, a plurality of hardware components may also be positioned on the circuit board and may also generate heat. To provide thermal management for the data processing system, the plurality of hardware components may be paired with a thermal dissipation component. A shape of the thermal dissipation component may conform to the plurality of hardware components.

### FIELD

Embodiments disclosed herein relate generally to management of data processing systems. More particularly, embodiments disclosed herein relate to systems and methods for thermal management of a data processing system.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a data processing system in accordance with an embodiment.

FIGS. 2A-2G show diagrams illustrating a thermal dissipation component in accordance with an embodiment.

FIG. 3 shows a flow diagram illustrating a method for thermal management of a data processing system in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to systems, devices, and methods for providing computer implemented services. To provide the computer implemented services, various data processing systems may be used. The data processing systems may include various hardware components that may generate heat which, if left unattended, may prevent desired operation of the hardware components.

To manage the generated heat, thermal dissipation components may be used. The thermal dissipation components may facilitate cooling of multiple hardware components at once. Various hardware components cooled by the thermal dissipation components may have different shapes, sizes, and geometries.

To accommodate these various hardware components, the thermal dissipation components may include adjustment mechanisms. The adjustment mechanisms may adjust various portions of the thermal dissipation components have shapes that are complementary to the hardware components. The complementary shapes may enable independent, direct thermal condition paths to each of the hardware components to be established. The conduction paths may enable heat generated by each of the hardware components to be dissipated.

In an embodiment, a data processing system that provides computer implemented services is provided.

This data processing system may include a chassis; a circuit board positioned in the chassis; a processor positioned with the circuit board and paired with a heatsink to dissipate heat generated by the processor; a plurality of hardware components positioned with the circuit board and paired with a thermal dissipation component; and the thermal dissipation component adapted to conform a portion of a shape of the thermal dissipation component to the plurality of hardware components to establish conduction paths between the plurality of hardware components and the thermal dissipation component to dissipate heat generated by all of the plurality of hardware components.

The thermal dissipation component may include a compliant coolant flow channel adapted to receive a coolant; establish a level of pressure within the compliant coolant flow channel using the coolant; and change the shape of the thermal dissipation component using the level of the pressure to place portions of the compliant coolant flow channel in direct contact with each of the plurality of hardware components.

The compliant coolant flow channel may include an entrance through which the coolant is received; a flow path that is in fluid communication with the entrance and that traverses proximate to each of the plurality of hardware components while the thermal dissipation component is attached to the circuit board; and an exit that is in fluid communication with the flow path and through which the coolant exits the compliant coolant flow channel.

The flow path may include a first portion adapted to make direct contact with a first component of the plurality of hardware components a first distance away from the flow path while the thermal dissipation component is attached to the circuit board, and a second portion adapted to make direct contact with a second component of the plurality of components a second distance away from the flow path while the thermal dissipation component is attached to the circuit board, wherein the first distance is different from the second distance.

The first portion may include a thermally conductive wall through which heat from the first component flows to reach the coolant in the first portion.

The thermally conductive wall may be part of a tube through which the coolant flows.

The thermal dissipation component may further include a pair of plates adapted to position the compliant coolant flow channel with respect to the plurality of hardware components; and constrain the change of the shape of the thermal dissipation component to direct the thermal dissipation component toward the plurality of hardware components. The tube may include a portion of the pair of plates.

The thermal dissipation component may further include a fin positioned with the portion of the pair of plates to dissipate heat from the coolant into an ambient environment.

The heatsink and the thermal dissipation component may be positioned in a coolant loop, and the heatsink may be positioned upstream of the thermal dissipation component.

In an embodiment, a thermal dissipation component for use with a data processing system is provided as discussed above.

In an embodiment, an enclosure that may include a thermal dissipation component is provided as discussed above.

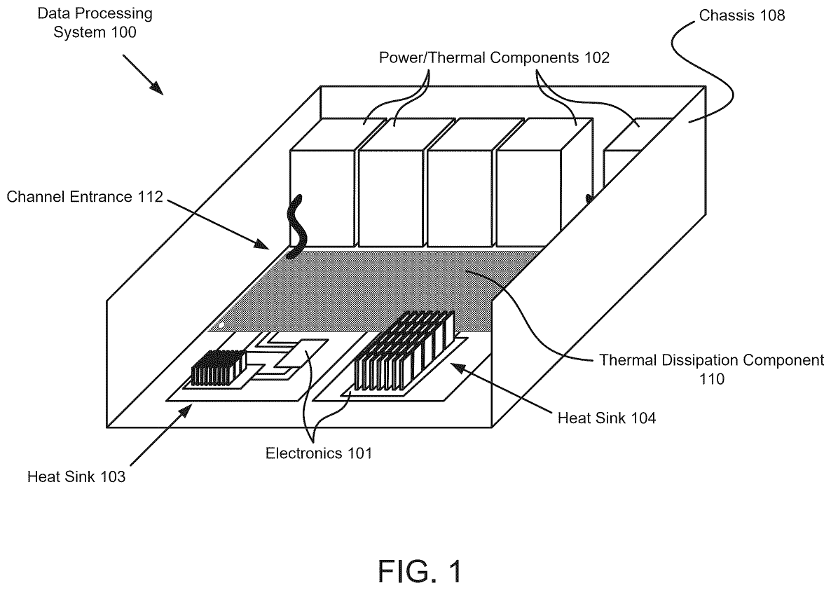

Turning to FIG. 1, a diagram illustrating a data processing system in accordance with an embodiment is shown. The data processing system shown in FIG. 1 may provide computer implemented services during its operation. The computer implemented services may include any type and/or quantity of computer implemented services. For example, the computer implemented services may include data storage services, instant messaging services, database services, and/or any other type of service that may be implemented with a computing device.

To provide the computer implemented services, the data processing system may include various hardware components. These hardware components may facilitate operation of a data processing system (e.g., 100) by performing various functionalities of the data processing system. For example, to provide the computer implemented services, data processing system 100 may include electronics 101, power/thermal components 102, and chassis 108. Each of these is discussed below.

Electronics 101 may include various types of hardware components such as processors, memory modules, storage devices, communications devices, and/or other types of devices. Any of these hardware components may be operably connected to one another using circuit board traces, cabling, connectors, etc. that establish electrical connections used to transmit information between the hardware components.

For example, data processing system 100 may include a central processing unit (CPU). This CPU (not explicitly shown in FIG. 1) may be capable of performing a high capacity of functionalities for data processing system 100 and may perform any number of these functionalities within a short amount of time.

It will be appreciated that a group of one or more of the hardware components operably connected to one another, and/or otherwise operably connected to data processing system 100, may be referred to as a plurality of hardware components. The plurality of hardware components may therefore include any type and/or quantity of hardware component such as those mentioned with regard to electronics 101. For example, electronics 101 may include the CPU and the plurality of hardware components, and each of these may perform the any number of functionalities.

To provide their functionalities, any of the hardware components may consume power and generate heat as a byproduct of operations performed using the electricity. Any of the hardware components may have a nominal operating thermal range (e.g., the hardware components may not operate properly outside of the nominal range). Generation of the heat may change temperatures of the hardware components that, if not managed, may cause the temperatures of the hardware components to fall outside of the nominal range. Consequently, the heat generated by the hardware components may prevent the computer implemented services from being provided if the heat is not managed properly.

In general, embodiments disclosed herein may relate to systems, devices, and methods for providing computer implemented services using data processing systems (e.g., 100). To provide the data processing systems, heat generated by hardware components may be proactively dissipated. To dissipate the heat, various heat dissipation modalities may be used. By dissipating the heat, a data processing system in accordance with an embodiment may be more likely to be able to provide desired computer implemented services, may be capable of operating in more challenging climates (e.g., higher temperature), and/or may have other benefits via the use of multiple heat dissipation modalities.

To provide the above noted functionality, data processing system 100 may include electronics 101, power/thermal components 102, heatsinks (e.g., 103-104), chassis 108, and thermal dissipation component 110. Each of these components is discussed below.

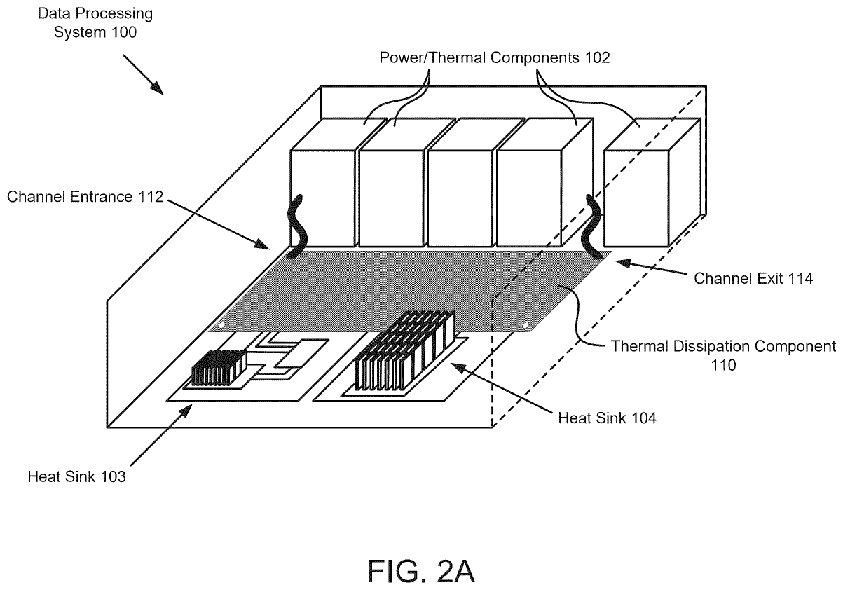

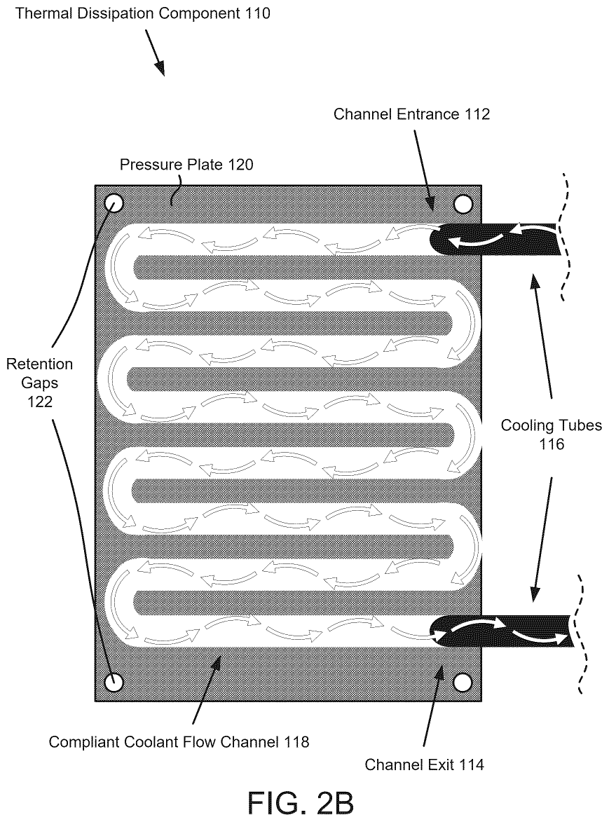

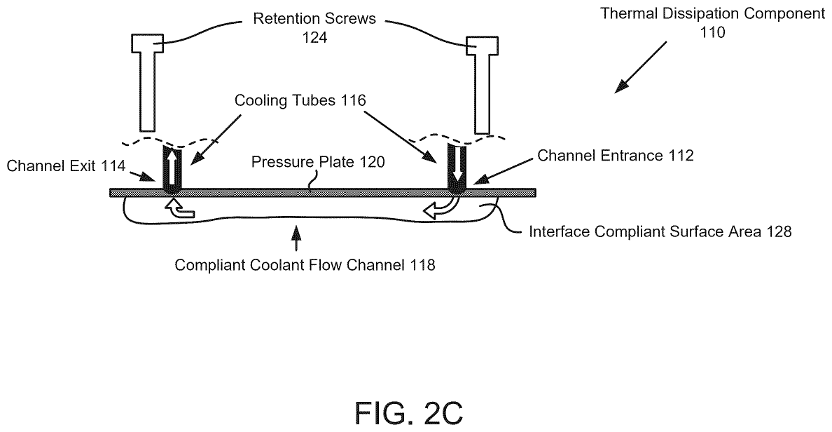

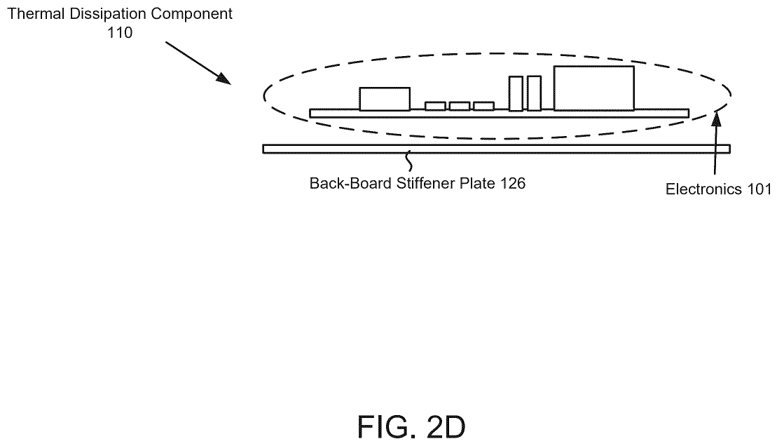

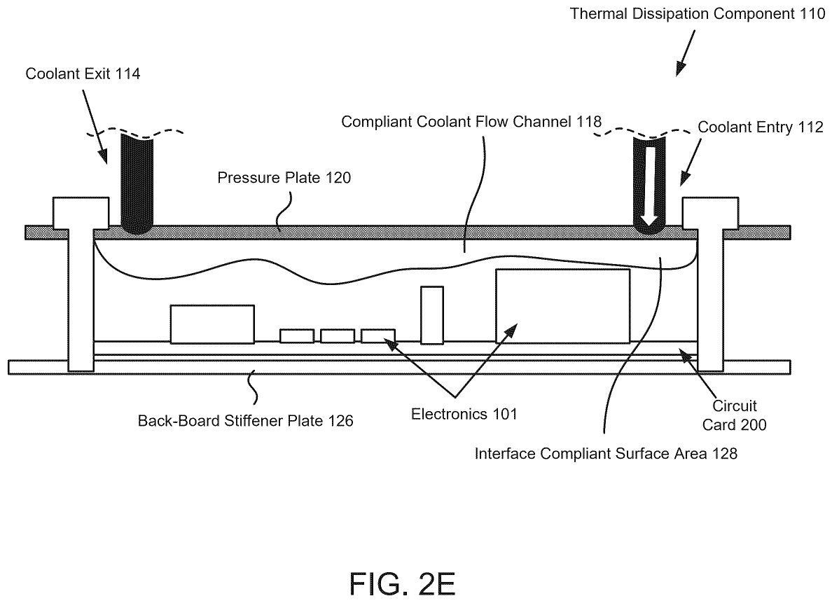

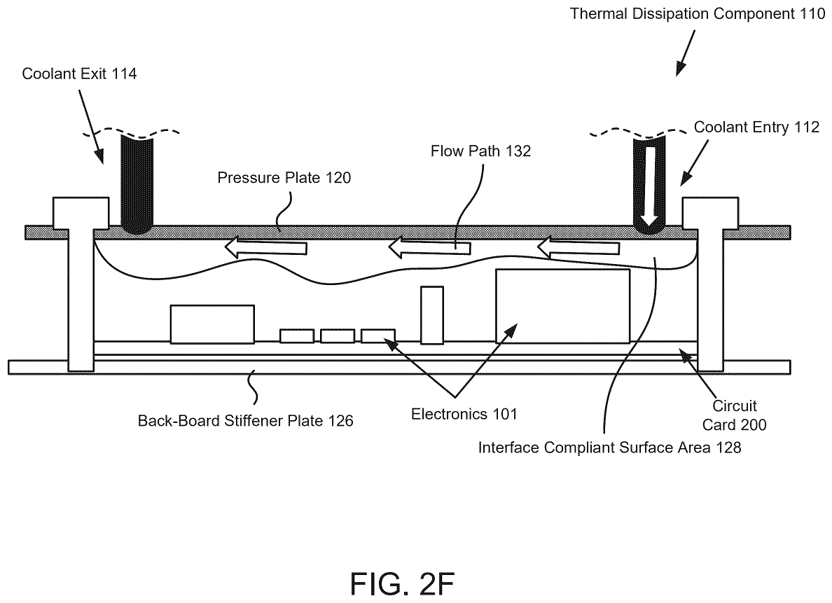

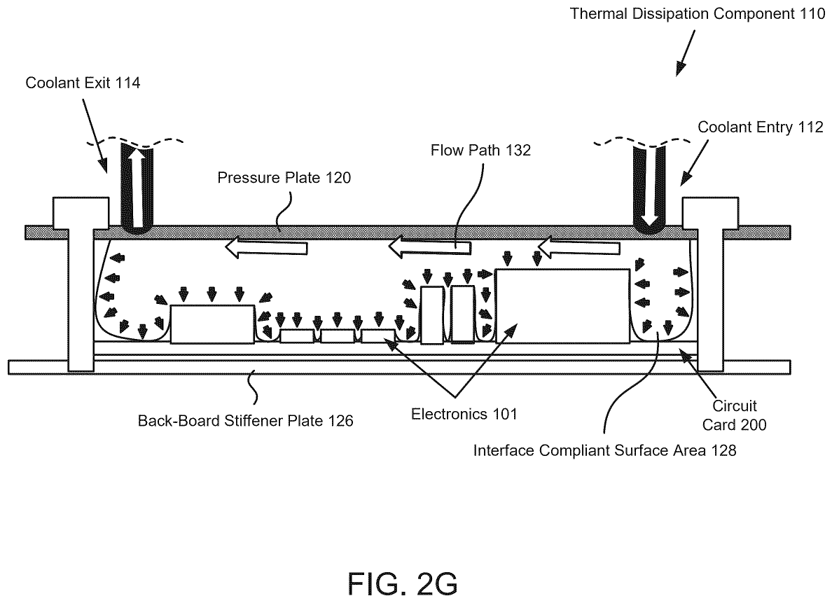

Electronics 101 may, as noted above, provide computer implemented services. Electronics 101 may include any number of hardware components. Any of the hardware components may be positioned on circuit cards (e.g., 200, FIG. 2E), and may generate heat during operation. Circuit cards may be pieces of circuit boards.

Power/thermal components 102 may power and/or thermally manage any of the components of data processing system 100. For example, power/thermal components 102 may include power components such as power supplies, and thermal components such as cooling fans, coolant reservoirs, chillers, coolant circulation pumps, and/or other components to facilitate performance of liquid-based cooling of some of electronics 101.

Heatsinks 103-104 may contribute to the thermal management of components by increasing surface areas for heat dissipation of respectively paired components. Cooling fans of power/thermal components 102 may direct air flow across the increased surface areas, thereby dissipating heat at a rate faster than if the components were not paired with the heatsinks. By pairing heatsinks with components and directing airflow across the heatsinks, components whose generated heat may have resulted in damage to data processing system 100 may instead be adequately cooled. However, in some cases, heatsinks may be insufficient to cool various components. To enhance cooling of some of the hardware components, data processing system 100 may include thermal dissipation component 110.

Thermal dissipation component 110 may facilitate cooling of any of electronics 101. To facilitate the cooling, thermal dissipation component 110 may be positioned with some of electronics 101, and may receive coolant circulated by power/thermal components 102. The coolant, while traversing thermal dissipation component 110, may absorb heat from some of the electronics 101. The coolant may circulate through a loop (e.g., via channel entrance 112), and be cooled by a cooling component such as a chiller (not shown). While power/thermal components 102 are shown as being part of data processing system 100, any of thermal components 102 may be positioned and/or otherwise be distinct from data processing system 100.

In contrast to heat sinks 103-104, thermal dissipation component 110 may cool multiple components of electronics 101 (e.g., of varying geometry). For example, thermal dissipation component 110 may be able to change its shape to be complementary to the components of electronics 101. Consequently, thermal conduction paths usable to extract heat from the portion of the components of electronics 101 may be established. Refer to FIGS. 2A-2G for additional details regarding thermal dissipation component 110.

Any of the components of data processing system 100 may be positioned in chassis 108. Chassis 108 may include an enclosure in which physical structures of electronics 101 (e.g., processors, memory, etc.), power/thermal components 102 (e.g., power supplies, fans, heatsinks 103-106, etc.), and/or other components may be positioned. For example, chassis 108 may facilitate placement and management of electronics 101 and/or other components in a computing environment.

While illustrated in FIG. 1 with a limited number of specific components, a data processing system may include additional, fewer, and/or different components without departing from embodiments disclosed herein.

To further clarify embodiments disclosed herein, diagrams illustrating examples of data processing systems (and portions thereof) in accordance with embodiments are shown in FIGS. 2A-2G.

Turning to FIG. 2A, a diagram illustrating thermal dissipation component 110 positioned with data processing system 100 in accordance with an embodiment is shown.

To cool some of the electronics in data processing system 100, thermal dissipation component 110 may be implemented as a plate having an adjustment mechanism. When positioned near electronics of various sized (e.g., by attaching to a circuit card), the adjustment mechanism may enable direct thermal conduction paths between multiple electronic components (of varying heights, for example) and thermal dissipation component 110.

Once in position, coolant may be flowed through thermal dissipation component 110. For example, coolant may be pumped into channel entrance 112 and may exit channel exit 114. While the coolant flows through thermal dissipation component 110, the direct conduction paths may cause heat generated by the electronic components to be deposited in the flowing coolant. The flow of the coolant may draw the heat out of thermal dissipation component 110, thereby cooling the electronic components.

In addition to thermal dissipation component 110, data processing system 100 may include various heat sinks. Like thermal dissipation component 110, heat sink 103 may cool an electronic device. However, there may generally be a 1:1 relationship between heat sinks and cooled components (e.g., as opposed to a N: 1 relationship of electronic components that are cooled by thermal dissipation component 110).

To facilitate cooling, heat sink 103 may include various mechanical structures (e.g., through hole bolts/attachment mechanisms) that may facilitate alignment and physical attachment of heat sink 103 to an electronic component thereby facilitating cooling of the electronic component. However, this approach may require significant use of board space from circuit cards. For example, rather than using board space for electronic transmission paths (e.g., metal strips), the limited real estate of the circuit cards may be dedicated to attachment points for the heatsink. Consequently, the density of electronics on the board may be reduced.

Further, as the size of the electronic components that are cooled decreased, the amount of circuit card space dedicated to attachment of heat sinks to the amount of cooling obtained from use of the heat sinks may decrease. Accordingly, at certain size scales, use of heat sinks to cool electronic components may become infeasible.

In contrast, by cooling multiple electronic components of various sized, thermal dissipation component 110 may exhibit a much higher ratio of cooling provided to board space utilized, when compared to heatsink 103. Thus, the use of thermal dissipation component 110 may improve cooling performance, reduce board space used for cooling, and/or may provide other benefits. Refer to FIGS. 2C-2E for additional information regarding attachment of thermal dissipation component 110 to a circuit card.

Turning to FIG. 2B, a top view diagram of thermal dissipation component 110 in accordance with an embodiment is shown. In FIG. 2B, some of a top surface of thermal dissipation component 110 is not illustrated to illustrate internal areas of thermal dissipation component 110. Additionally, oversized arrows with white fill are used to illustrate an example flow of coolant within thermal dissipation component 110.

To extract heat, coolant may be flowed through thermal dissipation component 110. To enable such flows, thermal dissipation component 110 may include compliant coolant flow channel 118 through which the coolant may flow.

To press the compliant coolant flow channel 118 against electronic components (e.g., into the page in FIG. 2B), a pressure plate 120 may be positioned with compliant coolant flow channel 118. For example, pressure plate 120 may be positioned above compliant coolant flow channel 118 while pressure plate 120 is attached to a circuit card on which electronic components are positioned.

Compliant coolant flow channel 118 may be a channel through which coolant may flow. A first end may be attached to channel entrance 112, and a second end may be attached to channel exit 114. The entrance/exit (e.g., 112/114) may include ports to which various tubes or other coolant carrying structures may attach. For example, coolant tubes 116 may be part of a coolant loop and may attach to the entrance/exit. The aforementioned configuration may cause coolant to flow through thermal dissipation component 110 in the pattern illustrated by the white oversized arrows.

Compliant coolant flow channel 118 may have a shape, size, and other characteristics adapted to facilitate thermal exchange with components positioned below pressure plate 120. For example, compliant coolant flow channel 118 may have serpentine shape, which cause coolant to flow over most of the underside of pressure plate. Thus, positioning of an electronic component anywhere under pressure plate 120 may ensure flows of coolant are proximate to the electronic component. Accordingly, the electronic component may be more likely to be cooled.

To facilitate placement and alignment of pressure plate 120 with respect to electronic components, pressure plate 120 may include retention gaps 122. Retention gaps 122 may be structures (e.g., holes) in pressure plate 120 to facilitate attachment of pressure plate 120 to other structures. Refer to FIG. 2C for additional details regarding thermal dissipation component 110.

Turning to FIG. 2C, a first side view diagram of thermal dissipation component 110 in accordance with an embodiment is shown.

To facilitate attachment of thermal dissipation component 110, retention screws 124 may be utilized. Retention screws 123 may be positioned with and through retention gaps 122. When so positioned, retention screws 124 may traverse through similar structures in circuit cards and/or stiffening plates, discussed in greater detail below. Retention screws 124, by virtue of this positioning, may retain thermal dissipation component 110 in a particular position with respect to electronic components on a circuit card.

To dissipate heat, as discussed above, coolant may flow through compliant coolant flow channel 118. Because various electronic components positioned below pressure plate 120 may be of varying topologies (e.g., different heights, widths, etc.), compliant coolant flow channel 118 may include an adaptable mechanism such as interface compliant surface area 128. Interface compliant surface area 128 may be an expandable portion of compliant coolant flow channel 118. When coolant is pumped into the interior of compliant coolant flow channel 118, interface compliant surface area 128 may expand (e.g., downward on the page in FIG. 2C) to close fill in any gap between pressure plate 120 and electronic components below pressure plate 120. By doing so, direct conduction paths may be established.

Turning to FIG. 2D, a second side view diagram of thermal dissipation component 110 in accordance with an embodiment is shown.

In addition to the components shown in FIG. 2C, thermal dissipation component 110 may include back-board stiffener plate 126. Back-board stiffener plate 126 may be a structure positioned on a side opposite of electronics 101 from the rest of thermal dissipation component 110. The screws (e.g., 124) may traverse through pressure plate 120, a circuit card of electronics 101, and through (and/or attach to) back-board stiffener plate 126. Back-board stiffener plate 126 may be a rigid structure, and when so attached may limit the space between it and pressure plate 120. Consequently, when interface compliant surface area 128 expands, it may fill in any space left between pressure plate 120 and electronics 101 (e.g., since back-board stiffener plate 126 prevents electronics from moving away from pressure plate 120.

Turning to FIG. 2E, a third side view diagram of thermal dissipation component 110 in accordance with an embodiment is shown. In FIG. 2E, thermal dissipation component 110 is depicted as being positioned with some electronics, but before coolant flows through compliant coolant flow channel 118.

As seen from FIG. 2E, in this configuration, interface compliant surface area 128 has not expanded to conform its shape to that of the electronics. For example, compliant coolant flow channel 118 may be constructed using a rubber or other material that may expand when the internal pressure within it exceeds a certain level. Thus, flowing coolant under pressure into compliant coolant flow channel 118 may cause interface compliant surface area 128 to expand towards and make contact with various electronic components.

Turning to FIG. 2F, a fourth side view diagram of thermal dissipation component 110 in accordance with an embodiment is shown. In FIG. 2F, thermal dissipation component 110 is depicted as being positioned with some electronics, and immediately following initiation of coolant flows through compliant coolant flow channel 118.

As seen in FIG. 2F, as coolant flows via flow path 132 (via compliant coolant flow channel 118), pressure may begin to build thereby causing interface compliant surface area 128 to expand towards the electronics. However, while contact has not yet been made with all electronic components in FIG. 2F, continued pressurization of the compliant coolant flow channel may cause such direct contact to be made.

Turning to FIG. 2G, a fifth side view diagram of thermal dissipation component 110 in accordance with an embodiment is shown. In FIG. 2G, thermal dissipation component 110 is depicted as being positioned with some electronics, and coolant flows through compliant coolant flow channel 118 for some time.

As seen in FIG. 2G, the flow (e.g., depicted with oversized arrows with white fill) and pressurization (e.g., depicted using oversized arrows with black fill) of coolant within the compliant coolant flow channel 118 may cause interface compliant surface 128 to expand. The expansion may be limited by the electronic components positioned between pressure plate 120 and back-board stiffener plate 126. Consequently, the shape of interface compliant surface area 128 may conform to the electronic components. Accordingly, direct thermal conduction paths between the compliant coolant flow path and the electronic components may be established.

These direct thermal conductions paths may allow heat from multiple electronic components to flow into the coolant flowing through thermal dissipation component 110.

For example, thermal dissipation component 110 may be positioned with multiple support chips that serve various central processing units. Thermal dissipation component 110 may be positioned in line with and downstream from liquid cooling blocks used to cool the central processing units. The coolant may be first circulated to the cooling blocks and then to thermal dissipation component 110 in series.

While described with an example coolant flow topology, it will be appreciated that thermal dissipation component 110 may be used in other coolant flow topologies (e.g., thermal dissipation component 110 may be in parallel with the coolant blocks, and/or may be in separate coolant loops).

The electronic components cooled by thermal dissipation component 110 may include any number and type of thermal components. For example, the electronic components may include (i) processors, (ii) controllers, (iii) communication chips, (iv) digital signal processors (v) programmable storage, (vi) memory, etc.

Additionally, while illustrated and described as using coolant, it will be appreciated that thermal dissipation component 110 may be implemented as a hybrid liquid/air cooling component. In such scenarios, various thermal dissipation components such as fins may be positioned with pressure plate 120.

Compliant coolant flow channel 118 may be implemented using any type of adaptable material and/or structure. For example, compliant coolant flow channel 118 may be implemented as a tube made of an expandable material. One or more sides of the tube may be bounded by pressure plate 120. Compliant coolant flow channel 118 may be attached to pressure plate 120 by, for example, using adhesive or other types of bonding systems.

While coolant is illustrated in FIGS. 2A-2G as entering compliant coolant flow channel 118 from a top side (e.g., through holes in pressure plate 120), it will be appreciated that coolant may enter through other surfaces (e.g., sides, below the pressure plate, and/or coming up through back-board stiffener plate 126, the circuit card, etc.).

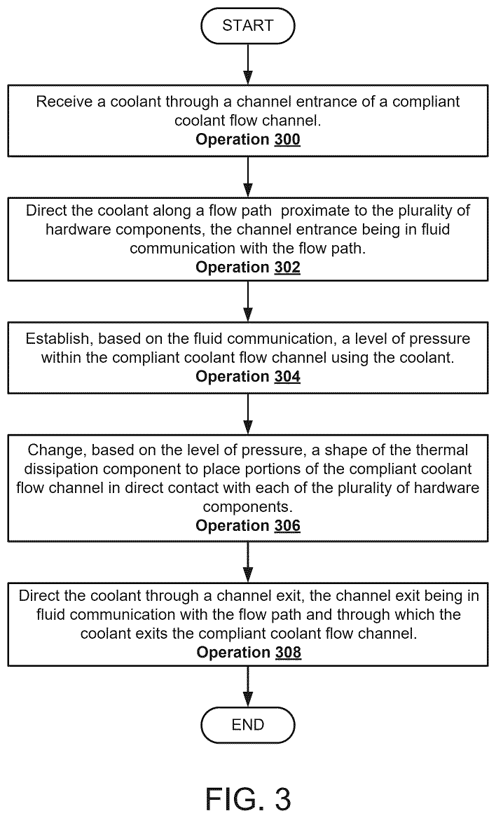

Thermal dissipation component 110 may be used in a variety of scenarios, and for various purposes. FIG. 3 shows a flow chart of method illustrating an example of a how a thermal dissipation component 110 in accordance with an embodiment may be used.

In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method for managing operation of a data processing system in accordance with an embodiment is shown. The method may be performed, for example, with a data processing system.

Prior to operation 300, a data processing system may be positioned in a data center. The data center may be a high density computer environment, and may supply coolant for use in cooling data processing systems. The data processing system may be positioned in the coolant loop, thereby enabling coolant to be circulated through the data processing system.

At operation 300, a coolant is received through a channel entrance of a compliant coolant flow channel. The coolant may be received by attaching tubes to the entrance and exit of a thermal dissipation component, that is positioned with various electronic components of varying heights and geometry.

At operation 302, the coolant is directed along a flow path proximate to a plurality of hardware components. The channel entrance may be in fluid communication with the flow path. The flow of coolant may be automatically directed along the flow path by virtue of the fluid communication between the entrance and a compliant coolant flow path within the thermal dissipation component. For example, external pumps may pump the coolant into the thermal dissipation component.

At operation 304, a level of pressure based on the fluid communication is established within the compliant coolant flow channel using the coolant. The level of pressure may be established by flowing the coolant at a predetermined rate, by position a choke (e.g., restriction in the line) in line with the compliant coolant flow channel, etc.

At operation 306, a shape of the thermal dissipation component is changed based on the level of pressure to place portions of the compliant coolant flow channel in direct contact with each of the plurality of hardware components. The shape may be changed by expansion of the compliant coolant flow channel, which may be made of a material that expands based on the pressure. The pressure may apply force to the material, which may deform (e.g., expand) until the pressure is reduced to certain levels.

At operation 308, the coolant is directed through a channel exit. The channel exit may be in fluid communication with the flow path, and through which the coolant exits the compliant coolant flow channel.

The method may end following operation 308.

Thus, using the method illustrated in FIG. 3, heat may be dissipated from any number of electronic components by establishing direct conduction paths with them. The conduction paths may cause heat to flow into a coolant within a compliant coolant flow path directly leading from the conduction paths.

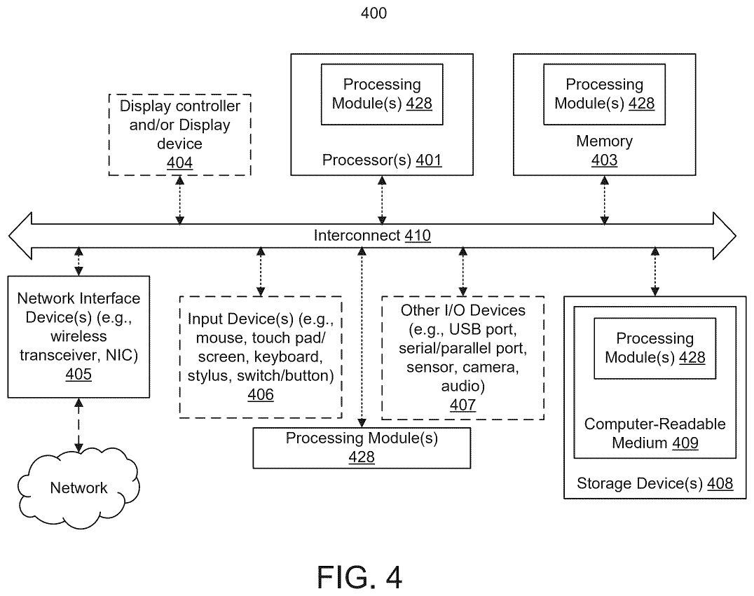

The aforementioned method, and thermal dissipation component described with respect to FIGS. 1-2G, may be used with a data processing system to facilitate cooling of components of the data processing system. Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a chassis;
a circuit board positioned in the chassis;
a processor positioned with the circuit board and paired with a heatsink to dissipate heat generated by the processor;
a plurality of hardware components positioned with the circuit board and paired with a thermal dissipation component; and
the thermal dissipation component adapted to:
conform a portion of a shape of the thermal dissipation component to the plurality of hardware components to establish conduction paths between the plurality of hardware components and the thermal dissipation component to dissipate heat generated by all of the plurality of hardware components.

2. The data processing system of claim 1, wherein the thermal dissipation component comprises:
a compliant coolant flow channel adapted to:
receive a coolant;
establish a level of pressure within the compliant coolant flow channel using the coolant; and
change the shape of the thermal dissipation component using the level of the pressure to place portions of the compliant coolant flow channel in direct contact with each of the plurality of hardware components.

3. The data processing system of claim 2, wherein the compliant coolant flow channel comprises:
an entrance through which the coolant is received;
a flow path that is in fluid communication with the entrance and that traverses proximate to each of the plurality of hardware components while the thermal dissipation component is attached to the circuit board; and
an exit that is in fluid communication with the flow path and through which the coolant exits the compliant coolant flow channel.

4. The data processing system of claim 3, wherein the flow path comprises:
a first portion adapted to make direct contact with a first component of the plurality of hardware components a first distance away from the flow path while the thermal dissipation component is attached to the circuit board, and
a second portion adapted to make direct contact with a second component of the plurality of components a second distance away from the flow path while the thermal dissipation component is attached to the circuit board,
wherein the first distance is different from the second distance.

5. The data processing system of claim 4, wherein the first portion comprises a thermally conductive wall through which heat from the first component flows to reach the coolant in the first portion.

6. The data processing system of claim 5, wherein the thermally conductive wall is part of a tube through which the coolant flows.

7. The data processing system of claim 6, wherein the thermal dissipation component further comprises:
a pair of plates adapted to:
position the compliant coolant flow channel with respect to the plurality of hardware components; and
constrain the change of the shape of the thermal dissipation component to direct the thermal dissipation component toward the plurality of hardware components.

8. The data processing system of claim 7, wherein the tube comprises a portion of the pair of plates.

9. The data processing system of claim 8, wherein the thermal dissipation component further comprises a fin positioned with the portion of the pair of plates to dissipate heat from the coolant into an ambient environment.

10. The data processing system of claim 1, wherein the heatsink and the thermal dissipation component are positioned in a coolant loop, and the heatsink is positioned upstream of the thermal dissipation component.

11. A chassis for a data processing system, comprising:
a receptacle for receiving a circuit board, a processor positioned with the circuit board and paired with a heatsink to dissipate heat generated by the processor, and a plurality of hardware components positioned with the circuit board and paired with a thermal dissipation component, the receptacle being inside the chassis; and
the thermal dissipation component adapted to:
conform a portion of a shape of the thermal dissipation component to the plurality of hardware components to establish conduction paths between the plurality of hardware components and the thermal dissipation component to dissipate heat generated by all of the plurality of hardware components.

12. The chassis of claim 11, wherein the thermal dissipation component comprises:
a compliant coolant flow channel adapted to:
receive a coolant;
establish a level of pressure within the compliant coolant flow channel using the coolant; and
change the shape of the thermal dissipation component using the level of the pressure to place portions of the compliant coolant flow channel in direct contact with each of the plurality of hardware components.

13. The chassis of claim 12, wherein the compliant coolant flow channel comprises:
an entrance through which the coolant is received;
a flow path that is in fluid communication with the entrance and that traverses proximate to each of the plurality of hardware components while the thermal dissipation component is attached to the circuit board; and
an exit that is in fluid communication with the flow path and through which the coolant exits the compliant coolant flow channel.

14. The chassis of claim 13, wherein the flow path comprises:
a first portion adapted to make direct contact with a first component of the plurality of components a first distance away from the flow path while the thermal dissipation component is attached to the circuit board, and
a second portion adapted to make direct contact with a second component of the plurality of components a second distance away from the flow path while the thermal dissipation component is attached to the circuit board,
wherein the first distance is different from the second distance.

15. The chassis of claim 14, wherein the first portion comprises a thermally conductive wall through which heat from the first component flows to reach the coolant in the first portion.

16. The chassis of claim 15, wherein the thermally conductive wall is part of a tube through which the coolant flows.

17. The chassis of claim 16, wherein the thermal dissipation component further comprises:
a pair of plates adapted to:
position the compliant coolant flow channel with respect to the plurality of hardware components; and
constrain the change the shape of the thermal dissipation component to direct the thermal dissipation component toward the plurality of hardware components.

18. The chassis of claim 17, wherein the tube comprises a portion of the pair of plates.

19. The chassis of claim 18, wherein the thermal dissipation component further comprises a fin positioned with the portion of the pair of plates to dissipate heat from the coolant into an ambient environment.

20. A thermal dissipation component for use with a data processing system, the thermal dissipation component comprising:
a compliant coolant flow channel adapted to:
receive a coolant,
establish a level of pressure within the compliant coolant flow channel using the coolant, and
change the shape of the thermal dissipation component using the level of the pressure to place portions of the compliant coolant flow channel in direct contact with a plurality of hardware components positioned on a circuit board while the thermal dissipation component is attached to the circuit board; and
a pair of plates adapted to attach the thermal dissipation component to the circuit board.
